(19) United States
(12) Patent Application Publication
(10) Pub. No.: US 2014/0141553 A1
(43) Pub. Date: May 22, 2014

(54) METHOD FOR MANUFACTURING LIGHT EMITTING DIODE CHIP

(71) Applicant: ADVANCED OPTOELECTRONIC TECHNOLOGY, INC., Hsinchu Hsien (TW)

(72) Inventors: CHING-HSUEH CHIU, Hsinchu (TW); YA-WEN LIN, Hsinchu (TW); PO-MIN TU, Hsinchu (TW); SHIH-CHENG HUANG, Hsinchu (TW)

(73) Assignee: ADVANCED OPTOELECTRONIC TECHNOLOGY, INC., Hsinchu Hsien (TW)

(21) Appl. No.: 14/035,958

(22) Filed: Sep. 25, 2013

(30) Foreign Application Priority Data
Nov. 21, 2012 (CN) 2012104746500

(51) Int. Cl. H01L 33/24

(52) U.S. Cl. CPC H01L 33/24
USPC 438/29

(57) ABSTRACT

A method for manufacturing a light emitting diode chip includes following steps: providing a sapphire substrate, the sapphire substrate having a plurality of protrusions on an upper surface thereof; forming an un-doped GaN layer on the upper surface of the sapphire substrate, the un-doped GaN layer totally covering the protrusions; forming a plurality of semiconductor islands on an upper surface of the un-doped GaN layer by self-organized growth, gaps being formed between two adjacent semiconductor islands to expose a part of the upper surface of the un-doped GaN layer; forming an n-type GaN layer on the exposed part of the upper surface of the un-doped GaN layer, the n-type GaN layer being laterally grown to totally cover the semiconductor islands; forming an active layer on an upper surface of the n-type GaN layer; and forming a p-type GaN layer on the active layer.

### BACKGROUND

1. Technical Field

The disclosure generally relates to a method for manufacturing an LED chip, wherein the lattice dislocations and defects of the LED chip are lowered whereby light extraction efficiency is increased.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

In epitaxial growth of an LED chip, one problem is how to reduce lattice defects in the semiconductor layers. One way to reduce the lattice defects is to provide a pattered sapphire substrate. By forming a plurality of protrusions on the sapphire substrate, semiconductor layers will be laterally grown from the protrusions, thereby reducing the lattice defects in the semiconductor layers. However, in the process described above, the semiconductor layer directly grows from a bottom of the protrusions will still have lattice defects, and the lattice defects are easy to concentrate on a top side of the protrusions to affect growth of following semiconductor layers.

What is needed, therefore, is a method for manufacturing an LED chip to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 shows a first step of a method for manufacturing an LED chip in accordance with an embodiment of the present disclosure.

FIG. 2 shows a second step of the method for manufacturing the LED chip in accordance with an embodiment of the present disclosure.

FIG. 3 shows a third step of the method for manufacturing the LED chip in accordance with an embodiment of the present disclosure.

FIG. 4 shows a fourth step of the method for manufacturing the LED chip in accordance with an embodiment of the present disclosure.

FIG. 5 shows a fifth step of the method for manufacturing the LED chip in accordance with an embodiment of the present disclosure.

### DETAILED DESCRIPTION

An embodiment of a method for manufacturing an LED chip will now be described in detail below and with reference to the drawings.

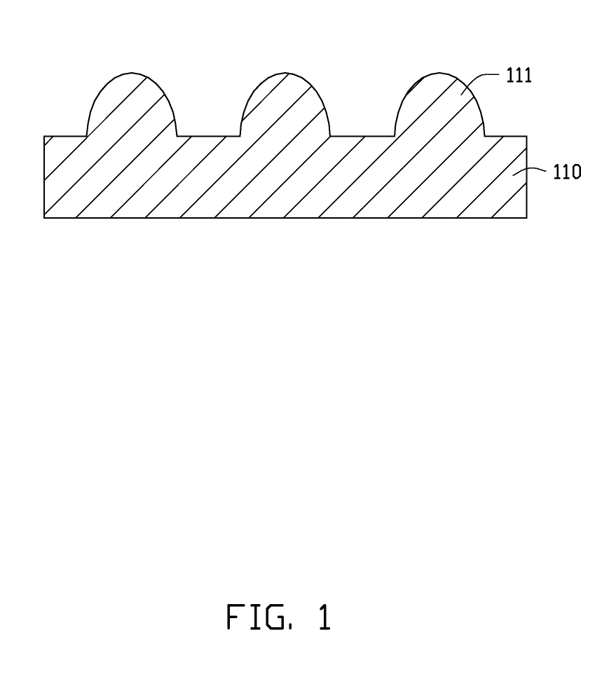

Referring to FIG. 1, a sapphire substrate 110 is provided. The sapphire substrate 110 has a plurality of protrusions 111 on an upper surface thereof. In this embodiment, each of the protrusions 111 has a semicircular cross section. In alternative embodiments, the cross section of each of the protrusions 111 can be triangular, trapezoid, or other polygons.

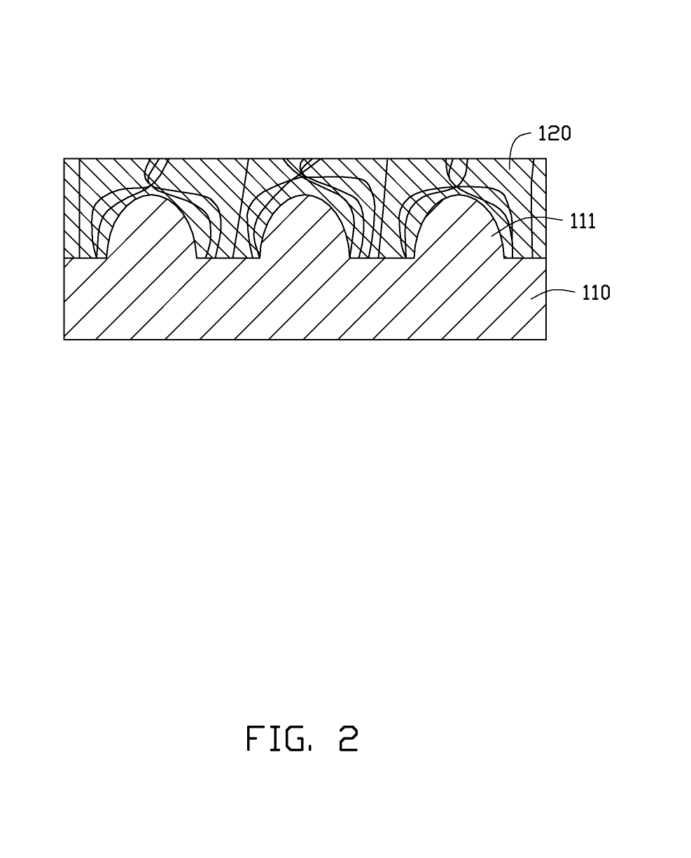

Referring to FIG. 2, an un-doped GaN layer 120 is formed on the upper surface of the sapphire substrate 110. The un-doped GaN layer 120 totally covers the protrusions 111.

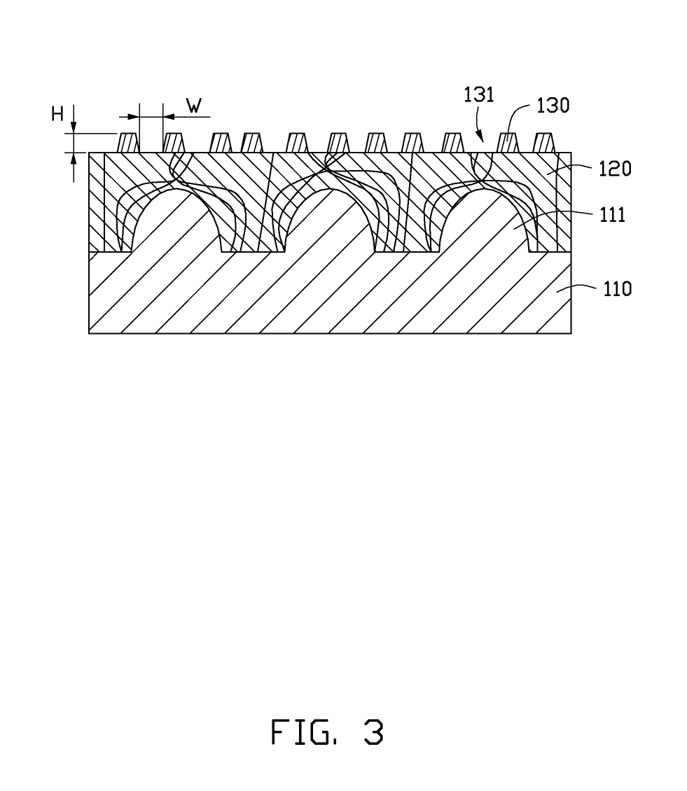

Referring to FIG. 3, a plurality of semiconductor islands 130 are formed on an upper surface of the un-doped GaN layer 120 by self-organized growth. Gaps 131 are formed between two adjacent semiconductor islands 130 to expose a part of the upper surface of the un-doped GaN layer 120. In this embodiment, the semiconductor islands 130 are made of SiNₓ. In self-organized growth of the semiconductor islands 130, SiH₄ gas and NH₃ gas are introduced to the upper surface of the un-doped GaN layer 120. The SiH₄ gas will react with the NH₃ gas to form the semiconductor islands 130 which has a composition of SiNₓ. The semiconductor islands 130 each have a height H in a range from 50 nm to 300 nm. Preferably, the semiconductor islands 130 each have a height H about 100 nm. The semiconductor islands 130 each have a width W less than 50 nm. Preferably, the semiconductor islands 130 each have a width about 10 nm.

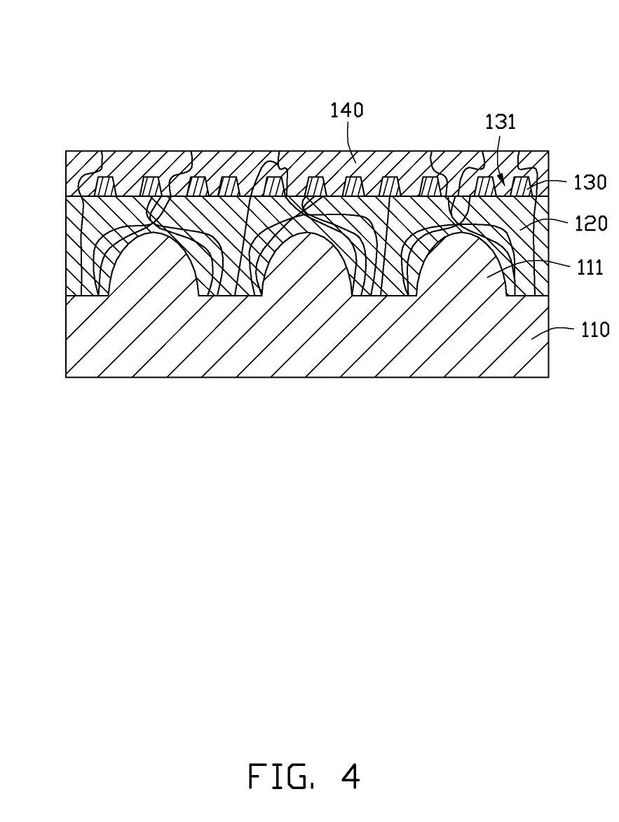

Referring to FIG. 4, an n-type GaN layer 140 is formed on the exposed part of the upper surface of the n-doped GaN layer 120 and the semiconductor islands 130. The n-type GaN layer 140 is filled in the gaps 131 between two adjacent semiconductor islands 130, and totally covers the semiconductor islands 130.

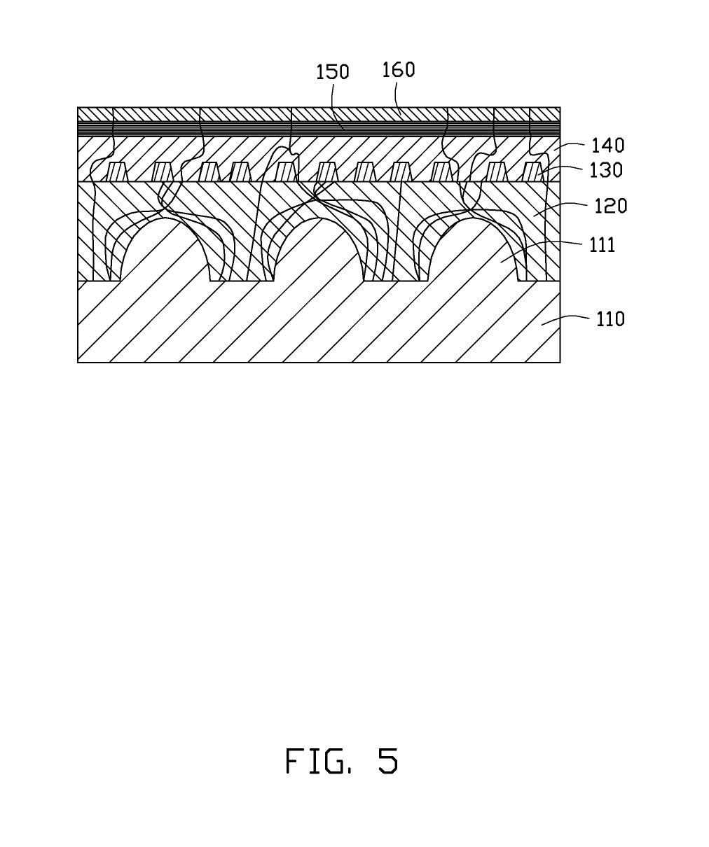

Referring to FIG. 5, an active layer 150 and a p-type GaN layer 160 are formed on an upper surface of the n-type GaN layer 140 in sequence. In this embodiment, the active layer 150 is a multiple quantum well (MQW) layer.

In the method for manufacturing the LED chip described above, a plurality of semiconductor islands 130 are formed on the un-doped GaN layer 120 by self-organized growth. Since the semiconductor islands 130 formed by self-organized growth are easy to grow on a defects concentrating area, the semiconductor islands 130 will be located on the defects concentrating area, whereby the defects in the un-doped GaN layer 120 can be blocked by the semiconductor islands 130 from extending upwardly into the n-type GaN layer 140, the active layer 150 and the p-type GaN layer 160. Therefore, defects in the n-type GaN layer 140, the active layer 150 and the p-type GaN layer 160 are reduced. Furthermore, because of the existence of the semiconductor islands 130, when the n-type GaN layer 140 grows on the exposed part of the un-doped GaN layer 120, the n-type GaN layer 140 is filled in the gaps 131 between the semiconductor islands 130 firstly, and then laterally grows to totally cover the semiconductor islands 130. The lateral growth of the n-type GaN layer 140 will further reduce the defects in the n-type GaN layer 140, the active layer 150 and the p-type GaN layer 160.

In an alternative embodiment, the semiconductor islands 130 are made of MgNₓ. In this alternative embodiment, during formation of the semiconductor islands 130 by self-organized growth, Cp₂Mg gas and NH₃ gas are introduced to the upper surface of the un-doped GaN layer 120. The Cp₂Mg gas will react with the NH₃ gas to form the semiconductor islands 130 which have a composition of MgNₓ.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing a light emitting diode chip, comprising:
providing a sapphire substrate, the sapphire substrate having a plurality of protrusions on an upper surface thereof;
forming an un-doped GaN layer on the upper surface of the sapphire substrate, the un-doped GaN layer totally covering the protrusions;
forming a plurality of semiconductor islands on an upper surface of the un-doped GaN layer by self-organized growth, gaps being formed between two adjacent semiconductor islands to expose a part of the upper surface of the un-doped GaN layer;
forming an n-type GaN layer on the exposed part of the upper surface of the un-doped GaN layer, the n-type GaN layer being laterally grown to totally cover the semiconductor islands;
forming an active layer on an upper surface of the n-type GaN layer; and
forming a p-type GaN layer on the active layer.

2. The method of claim 1, wherein the semiconductor islands formed by self-organized growth are made of SiNₓ.

3. The method of claim 2, wherein in the self-organized growth of the semiconductor islands, SiH₄ gas and NH₃ gas are introduced to the surface of the un-doped GaN layer, and the SiH₄ gas reacts with the NH₃ gas to form the semiconductor islands made of SiNₓ.

4. The method of claim 1, wherein the semiconductor islands formed by self-organized growth are made of MgNₓ.

5. The method of claim 4, wherein in the self-organized growth of the semiconductor islands, Cp₂Mg gas and NH₃ gas are introduced to the surface of the un-doped GaN layer, and the Cp₂Mg gas reacts with the NH₃ gas to form the semiconductor islands made of MgNₓ.

6. The method of claim 1, wherein the semiconductor islands each have a height in a range from 50 nm to 300 nm.

7. The method of claim 6, wherein the semiconductor islands each have a height about 100 nm.

8. The method of claim 1, wherein the semiconductor islands each have a width less than 50 nm.

9. The method of claim 8, wherein the semiconductor islands each have a width about 10 nm.

10. The method of claim 1, wherein the active layer is a multiple quantum well (MQW) layer.

11. A method for manufacturing a light emitting diode chip, comprising:
providing a sapphire substrate, the sapphire substrate having a plurality of protrusions on an upper surface thereof;
forming an un-doped GaN layer on the upper surface of the sapphire substrate, the un-doped GaN layer totally covering the protrusions;
forming a plurality of semiconductor islands on an upper surface of the un-doped GaN layer by self-organized growth, gaps being formed between two adjacent semiconductor islands to expose a part of the upper surface of the un-doped GaN layer;
forming an n-type GaN layer on the exposed part of the upper surface of the un-doped GaN layer, the n-type GaN layer filled in the gaps between two adjacent semiconductor islands and totally covering the semiconductor islands;
forming an active layer on an upper surface of the n-type GaN layer; and
forming a p-type GaN layer on the active layer.

12. The method of claim 11, wherein the semiconductor islands formed by self-organized growth are made of SiNₓ.

13. The method of claim 12, wherein in the self-organized growth of the semiconductor islands, SiH₄ gas and NH₃ gas are introduced to the surface of the un-doped GaN layer, and the SiH₄ gas reacts with the NH₃ gas to form the semiconductor islands made of SiNₓ.

14. The method of claim 11, wherein the semiconductor islands formed by self-organized growth are made of MgNₓ.

15. The method of claim 14, wherein in the self-organized growth of the semiconductor islands, Cp₂Mg gas and NH₃ gas are introduced to the surface of the un-doped GaN layer, and the Cp₂Mg gas reacts with the NH₃ gas to form the semiconductor islands made of MgNₓ.

16. The method of claim 11, wherein the semiconductor islands each have a height in a range from 50 nm to 300 nm.

17. The method of claim 16, wherein the semiconductor islands each have a height about 100 nm.

18. The method of claim 11, wherein the semiconductor islands each have a width less than 50 nm.

19. The method of claim 18, wherein the semiconductor islands each have a width about 10 nm.

20. The method of claim 11, wherein the active layer is a multiple quantum well (MQW) layer.
